(19) United States
(12) Patent Application Publication
(10) Pub. No.: US 2007/0166875 A1
(43) Pub. Date: Jul. 19, 2007

(54) Method of forming a microelectronic package and microelectronic package formed according to the method

(75) Inventor: Ganesh V. Vasudevanpillai, Chandler, AZ (US)

Correspondence Address: INTEL CORPORATION;c/o INTELLEVATE, LLC, P.O. BOX 52050, MINNEAPOLIS, MN, 55402, US

(73) Assignee: Intel Corporation

(21) Appl. No.: 11/323,521

(22) Filed: Dec. 29, 2005

(51) Int. Cl. H01L 21/00

(52) U.S. Cl. 438/106

(57) ABSTRACT

A microelectronic package, a substrate adapted to be used in forming the package, a method of forming the package, and a system including the package. The package includes a substrate; a die bonded to the substrate; a plurality of joint structures electrically bonding the die to the substrate. At least one of the plurality of joint structures comprises a layer including an alloy and intermetallic compound grains dispersed within the alloy, wherein: the alloy comprises a mixture of a first element and a second element both chosen such that a eutectic of the first element and second element has a melting temperature below a melting temperature of any element other than the eutectic in the at least one joint structure; and each of the intermetallic compound grains comprises a combination of the second element with a third element, wherein the third element is corrosion resistant.

### FIELD OF THE INVENTION

Embodiments of the present invention relate generally to methods of packaging microelectronic devices.

### BACKGROUND OF THE INVENTION

Flip-chip attach processes typically involve a reflow of solder bumps to form solder joints between a die and substrate. The substrate usually includes substrate bumping sites thereon, and the die includes die bumping sites thereon adapted to be joined to the substrate bumping sites to establish an electrical connection between the die and the substrate. The substrate and/or die bumping sites may include under bump metallization (UBM) including a copper layer on the die/substrate bonding pads, a nickel layer on the copper layer, and a gold layer on the nickel layer. The gold is usually provided for its inertness to attack by corrosive substances, i.e., for its corrosion resistance and to improve wettability of the molten solder, as is well known in the art. Solder bumps are provided onto bumping sites of the substrate and/or die. The nickel is usually provided as a barrier layer to prevent a migration of the copper from the copper layers to the solder. Typically, temperatures necessary to reflow the solder bumps lead to an expansion of each of the die and the substrate. During cooling, different shrinkage amounts of the die and substrate could lead to cracks within the die, especially when a mechanically weak interlayer dielectric (ILD) is used on the die. The ILD of the die usually tends to experience increased thermo-mechanical stresses in the area under the solder joints during die and substrate attach, which stresses lead to increased under bump ILD cracking. Because of the above disadvantages with effecting a direct joining of die and substrate, as mentioned above, underfill materials are sometimes used to compensate for the differences in CTE of the die and the substrate before the joint, die, and substrate cool down.

According to a flip-chip attach process involving a capillary underflow regime, as is well known, a flux material is first dispensed on the substrate bumping sites such as through a stencil. The flux material, as is well known, is provided to remove oxides and contaminants from the substrate bumping sites during a reflow of the solder joints for a contaminant free resulting solder joint. Thereafter, the die is placed over the substrate such that the die bumping sites are placed in registration with the substrate bumping sites. The package is then usually heated in a furnace in order to effect a reflow of the solder bumps such that the solder bumps can form solder joints between the die and substrate. After reflow, the package is subjected to a deflux process in which it is first placed under elevated pressures and subjected to heated de-ionized water to remove any flux residue from between the substrate and die, dried under hot air, and then subjected to pre-baking at elevated temperatures in order to remove any further moisture therefrom before underfill material is provided thereon. Then, underfill material is provided in the space between die and substrate by being initially dispensed close to one edge of the die. The underfill material thus dispensed tends to flow in the space between die and substrate through capillary action. Thereafter, the underfill material, typically comprising epoxy, is placed in a cure oven where the epoxy initially flows and then hardens to provide a seal and a mechanical bond between die and substrate, and to compensate for CTE differences therebetween. Disadvantageously, the capillary underflow regime requires a large number of process stages involving the provision and removal of flux, and thus tends to negatively affect process cost and throughput.

An alternative to the capillary underflow regime is the well known no-flow underfill or NUF regime, which involves using an underfill material already having a flux material therein. According to the NUF regime, the flux dispensing and deflux stages noted above are dispensed with. Thus, after an initial prebake stage to remove any moisture from the substrate and to preheat the substrate for the stages to follow, no-flow underfill material is dispensed onto the substrate and substrate bumping sites with the solder bumps thereon. Thereafter, the die is placed over the substrate such that the die bumping sites are placed in registration with the substrate bumping sites. The package is then placed in a thermal compression bonder, or TCB, and placed under elevated pressure and heated in order to effect a reflow of the solder bumps such that the solder bumps can form solder joints between the die and substrate. Here the no-flow underfill material is only partially cured. Thereafter, the package is placed in a cure oven in order to effect a full curing of the no-flow underfill material in order to harden the same and to provide a seal and a mechanical bond between die and substrate, and to compensate for CTE differences therebetween.

Disadvantageously, in the NUF regime, some underfill material tends to be entrapped between the die bumping sites and substrate bumping sites during thermal compression bonding and the post-curing process. Entrapped underfill in a solder joint as shown can become a location for voids and for crack initiation as a result of bump fatigue cracking in reliability stressing tests. In addition, entrapped underfill material can disadvantageously lead to solder electro-migration issues.

The prior art fails to provide a reliable, efficient, and cost-effective method of joining a die to a substrate.

### BRIEF DESCRIPTION OF THE DRAWINGS

FIG. 1 is a schematic cross-sectional view of a microelectronic package according to an embodiment;

FIG. 2 is a schematic cross-sectional view of one of the joint structures of the package of FIG. 1;

FIGS. 3-8 are schematic cross-sectional views showing stages in the formation of the joint structure of FIG. 2 according to an embodiment;

FIG. 9 is a schematic cross-sectional view of a bonded die-substrate combination obtained from following the stages of FIGS. 3-8;

FIG. 10 is a schematic cross-sectional view showing a dispensing of underfill material in a space between the die and the substrate of the combination of FIG. 9 according to an embodiment;

FIG. 11 is a graph showing an example of a temperature/pressure profile for joint structure and underfill cure according to an embodiment; and

FIG. 12 shows a system including a package such as the package of FIG. 1 according to an embodiment.

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a microelectronic package, a microelectronic substrate, a method of forming the package, and a system including the package are disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

The terms on, above, below, and adjacent as used herein refer to the position of one component relative to other components. As such, a first component disposed on, above, or below a second component may be directly in contact with the second component or it may include one or more intervening components. In addition, a first component disposed next to or adjacent a second component may be directly in contact with the second component or it may include one or more intervening components. In addition, a “layer” as used herein may refer to a layer made of a single material, a layer made of a mixture of different components, a layer made of various sub-layers, each sub-layer also having the same definition of layer as set forth above.

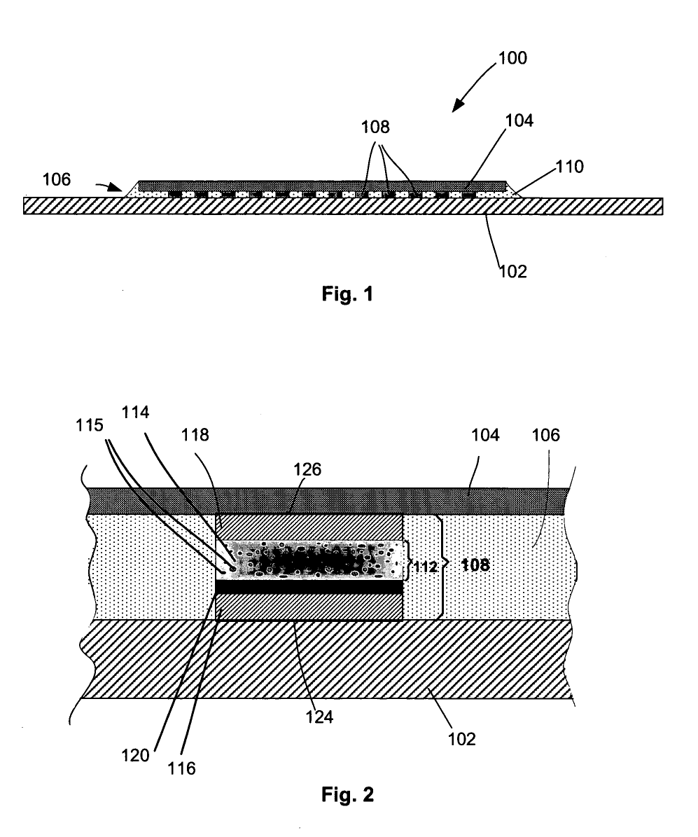

In one embodiment, a microelectronic package is disclosed. In one embodiment, a microelectronic substrate is disclosed. In another embodiment, a method to form a microelectronic package is disclosed. In yet another embodiment, a system including a microelectronic package is enclosed. Aspects of these and other embodiments will be discussed herein with respect to FIGS. 1-11, below. The figures, however, should not be taken to be limiting, as they are intended for the purpose of explanation and understanding.

In FIG. 1, an embodiment of a microelectronic package is disclosed. As seen in FIG. 1, a microelectronic package 100 includes a substrate 102, and a die 104 bonded to the substrate by a bond 106. By “bond,” what is referred to in the context of the present invention is at least an electrical joint between the die and the substrate. The bond may further include a mechanical joint between the die and the substrate. As seen in FIG. 1, a plurality of joint structures 108 are shown between the die and the substrate, the joint structures 108 forming part of bond 106 to at least electrically join the die to the substrate. In the shown embodiment, bond 106 further includes a cured underfill material 110, which may include any one of the underfill materials well known in the art, such as, for example, epoxy or the like.

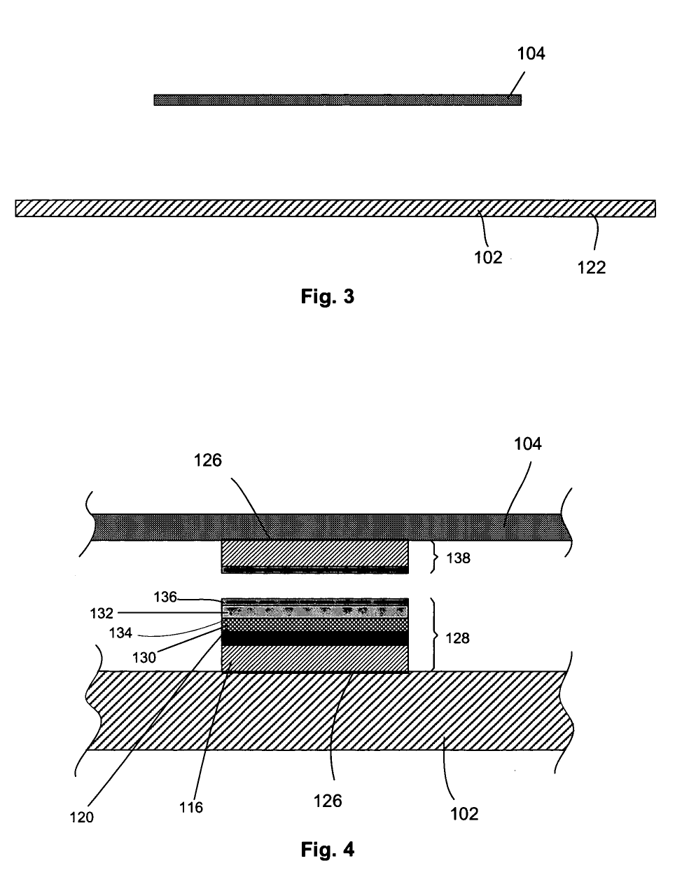

Referring now to FIG. 2, an embodiment is shown for at least one of the joint structures. In the shown embodiment, the at least one of the joint structures 108 includes a layer 112 comprising an alloy 114 and intermetallic compound grains 115 dispersed within the alloy. According to embodiments, the alloy comprises a mixture of a first element and a second element both chosen such that a eutectic of the first element and second element has a melting temperature below a melting temperature of any element other than the eutectic in the at least one joint structure. Preferably, the melting temperature of the eutectic is between about 115 degrees Centigrade and about 200 degrees Centigrade. Preferably, all of the joints structures exhibit substantially identical configurations. To the extent that the joint structures are to form an electrical bond between the die and substrate, it is understood that the first element and the second element are to be chosen such that the alloy is electrically conductive. In addition, each of the intermetallic compound grains comprises a combination of the second element with a third element, wherein the third element is corrosion resistant. By “corrosion resistant,” what is meant in the context of the instant description is the characteristic of resisting corrosion associated with oxidation by way of exposure to ambient conditions, especially during prebake before bonding. An element is “corrosion resistant” as used herein if it has a positive reduction potential. For example a reduction potential of Au is +1.69 V, and, as a result, Au is corrosion resistant and is a preferable choice to the third element. Other corrosion resistant elements which may be used as the third element according to embodiments include Ag, Pd and Pt. According to a preferred embodiment, the first element may comprise Sn, the second element may comprise In, the alloy may comprise SnIn, the intermetallic compound grains may comprise Auln2, and the third element may comprise gold. The alloy may comprise a eutectic alloy, or a non-eutectic alloy, such as a non-eutectic alloy comprising up to about 80 percent by weight Sn. A selection of a eutectic alloy versus a non-eutectic Sn rich alloy in the mentioned embodiments is a function of an expected operating temperature of the package. For example, if the expected operating temperature of the package is to be below 100 degrees Centigrade, then, a eutectic alloy would be best suited for the joint structure. If the usage temperature is higher than 100 degrees Centigrade, however, then, a non-eutectic alloy including a Sn percentage by weight that is higher than the eutectic percentage, that is, higher than 48% by weight, would be better suited for the joint structure. A reason for the above is that, as the percent by weight of Sn of the alloy increases from that associated with a eutectic alloy, the melting temperature of the joint structure will also increase. For example, if the composition is of the alloy includes 80% by weight of Sn, then the joint structure melting temperature would be about 200 degrees C. Additionally, according to one embodiment, the layer 112 comprises from about 97 to about 99 percent by weight of the alloy, and from about 1 to about 3 percent by weight of the intermetallic compound. Referring still to FIG. 2, accordingly to a preferred embodiment of the joint structures, the layer 112 in the joint structures 108 is a middle layer 112 disposed between a first electrically conductive layer 116 adjacent the substrate, and a second electrically conductive layer 118 adjacent the die. According to a preferred embodiment, the first and second electrically conductive layers comprise respective copper layers directly in contact with, respectively, the substrate and the die bonding pads, such as bonding pads 126 and 124, respectively. By “bonding pad,” what is meant in the context of the present description is the portion of the conductive pattern on printed circuits on either the die or the substrate designed to allow an electrical bonding of the die or substrate to external circuitry. The first and second electrically conductive layer may also comprise Al or Ag. Preferably, as seen in FIG. 2, a barrier layer 120, such as, for example, a layer comprising nickel, may be provided on the first conductive layer 116, or even on the second conductive layer 118 (not shown). By “barrier layer,” what is meant in the context of the present invention is a layer adapted to prevent a migration of electrically conductive material from the first electrically conductive material, as is recognized by persons skilled in the art. It is noted that, although the shown embodiment shows only the layers described above, embodiments comprise within their scope the provision of additional layers in the joint structure as long as the alloy and the intermetallic compound as described are present. As also seen in FIG. 2, a cured underfill material may be provided between the joint structures in the space between the die and the substrate. The cured underfill material may comprise any well known underfill material, such as, for example, epoxy. Preferably, the underfill material has a cure temperature equal to or below about 200 degrees Centigrade. According to one embodiment, the underfill material comprises an underfill material which may be dispensed according to a capillary underfill regime, and thereafter cured.

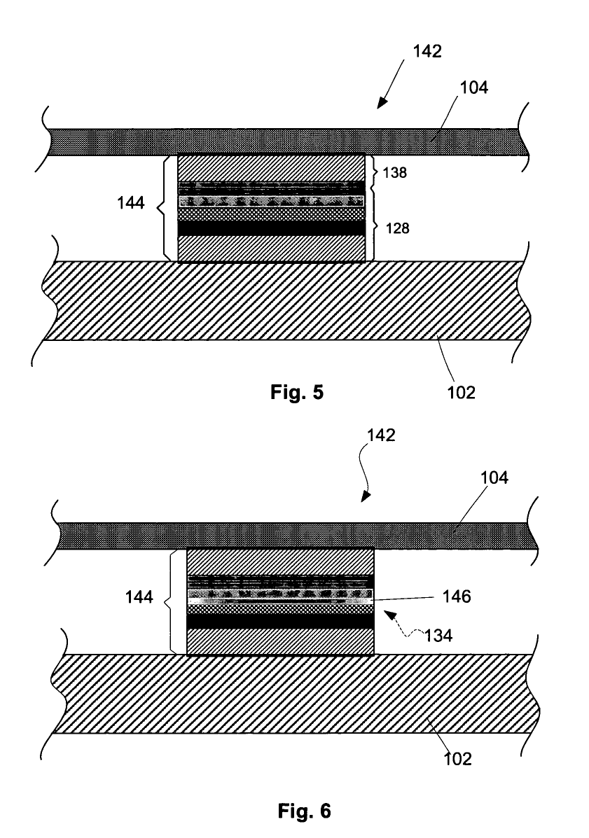

Referring next to FIGS. 3-10, a method embodiment to form a microelectronic package by such as the package of FIGS. 1-2 by bonding a die to a substrate will be described.

Referring now to FIG. 3 by way of example, embodiments contemplate the provision of a substrate 102 and of a die 104 to be bonded to the substrate. The substrate may include a wafer 122 including circuitry (not shown) within the wafer, the circuitry including a plurality of bonding pads 124, as would be recognized by one skilled in the art. The die may further include any microelectronic die including circuitry having bonding pads 126 as would be recognized by one skilled in the art.

Referring now to FIG. 4 by way of example, some embodiments contemplate providing bumping sites on the die bonding pads and on the substrate bonding pads. Thus, as seen in FIG. 4, embodiments contemplate providing bumping sites such as bumping site 128 on the substrate bonding pads 124 as shown. The substrate bumping site 128 include a layer 130 comprising the first element, such as, for example, Sn, layer 130 being disposed on the substrate 102. In the shown preferred embodiment, there is disposed the first electrically conductive layer 116 directly on the bonding pad 124, and the barrier layer 120 directly on the first electrically conductive layer 116, the layers 116 and 120 being disposed between the layer 130 comprising the first element and the substrate 102 as shown. Bumping site 128 further comprises a layer 132 comprising the second element, such as, for example, In, layer 132 being disposed on the layer 130 including the first element. Layers 116, 120,130 and 132 may be provided according to any one of well known methods, such as, for example, preferably, by way of electroless plating. The first element and the second element are selected such that a provision of layer 132 including the second element onto the layer 130 including the first element results in the formation of a eutectic 134 of the first element and the second element disposed at the interface between the layer 130 including the first element and the layer 132 including the second element. As noted above, the first element and the second element are selected such that the eutectic 134 has a melting temperature below a melting temperature of any element other than the eutectic in the joint structure, and, preferably, a melting temperature between about 115 degrees Centigrade and 200 degrees Centigrade. Onto the layer 132 including the second element is provided, according to embodiments, a layer 136 including the third element, such as, for example, Au. Layer 136 may be provided in the form of a gold cap, according to any one of well known methods, such as, for example, preferably, by way of electrolytic (or immersion) plating. According to an embodiment, a total thickness of the layer 130 including the first element, the layer 132 including the second element, and the layer 136 including the third element, is from about 15 to about 20 microns. A thickness of the layer 136 including the third element, according to an embodiment, may be about 50 nanometers to resist a corrosion of at least the second element by preventing a coming into contact of the layer including the second element with ambient conditions. Optionally, according to an embodiment, prior to a provision of the bumping sites on the substrate, the substrate may be subjected to a prebake in a well known manner, such as by being heated to a temperature between about 90 and about 110 degrees Centigrade.

Thicknesses of the layer 130 including the first element and of the layer 132 including the second element are a function of, among other things, an expected temperature environment of the package during its operation. For example, in a preferred embodiment where the first element is Sn and the second element in In, for a low temperature operating environment (or low temperature application) of the package, such as, for example, an operating temperature below about 110 degrees Centigrade, a thickness of layer 130 including Sn would be about 8 microns, and a thickness of layer 132 including In would be about 7 microns, for a total thickness of about 15 microns. For temperatures above the range mentioned above, a thickness of the layer 130 including Sn would be increased relative to the layer 132 including In to increase a melting point of the resulting joint structure, based for example on a consideration of a Sn and In phase diagram, as would be within the knowledge of one skilled in the art. Referring still to FIG. 4 by way of example, an embodiment may further include the provision of bumping sites on the die bumping pads 126. Thus, in a preferred embodiment, die bumping sites 138 may include the second electrically conductive layer 118, and a layer 140 including the third element, comprising, for example, a gold cap thereon. The first and second conductive layers, such as, for example, copper layers, may be provided according to any one of well known methods, such as, for example, through electroless or electrolytic plating, as would be recognized by one skilled in the art.

Referring next to FIG. 5 by way of example, embodiments comprise placing the die 104 onto the substrate 102 such that the substrate bumping sites 128 and the die bumping sites 138 are placed in registration with one another to form a die-substrate combination 142 including pairs such as pair 144 of registered die and substrate bumping sites.

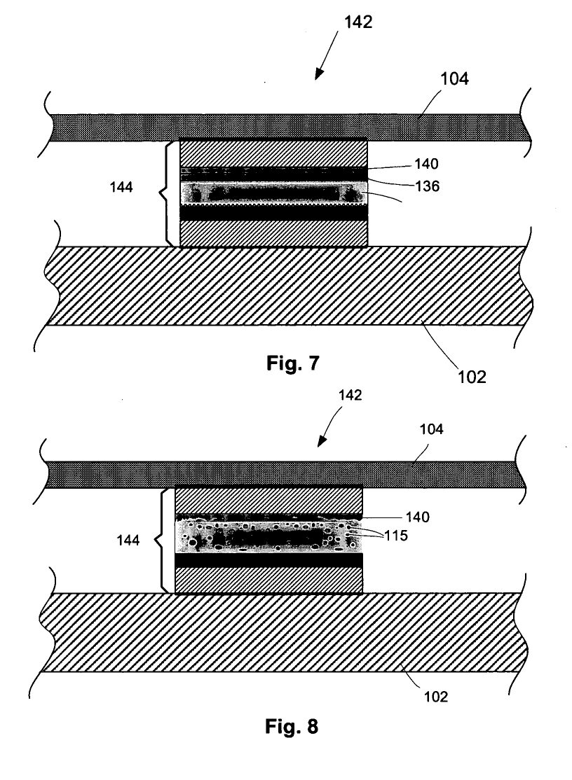

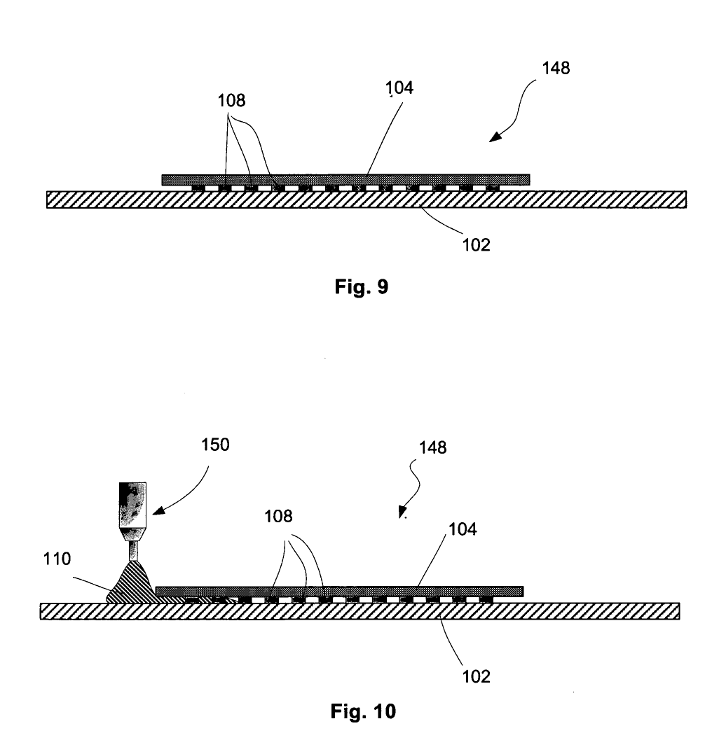

Referring next to FIGS. 6-8 by way of example, embodiments include forming joint structures from each pair 144 of die and substrate bumping sites including heating the die-substrate combination 142 within a heating temperature range equal to or above a melting temperature of the eutectic, but below a melting temperature of any other element present in the joint structure, and further applying pressure to the die-substrate combination, to bond the die to the substrate. A joint formation according to embodiments involves diffusion bonding as will be explained in further detail below, and may take place within a time frame between about 5 minutes and about 10 minutes according to a preferred embodiment. Preferably, the heating temperature range is between about 115 degrees Centigrade and 200 degrees Centigrade. Preferably, the heating temperature is about 125 degrees Centigrade (for a eutectic Snin composition) during joint solidification. A heating temperature range for heating the die-substrate combination may be obtained from a phase diagram of the first and second elements, as would be recognized by one skilled in the art. For example, where the first element comprises Sn and the second element comprises In, a Sn-In phase diagram would indicate that a heating temperature range for the die-substrate combination would increase as the Sn percent by weight of the composition increases. In addition, preferably, a pressure applied may be in the range between about 4 Newtons and about 8 Newtons. Preferably, the pressure applied is substantially constant during a heating of the die-substrate combination. More preferably, a heating of the die-substrate combination and a pressure application involving the die-substrate combination in order to form the joint structures includes using a thermal compression bonder, such as one typically used in a NUF process. Most preferably, as will be explained in further detail with respect to FIGS. 9 and 10, an underfill material is not dispensed between the die and the substrate until after formation of the joint structures. Heating according to embodiments where an underfill material is to be dispensed in a space between the die and substrate at a subsequent bonding stage may further advantageously serve as a prebake before dispensing the underfill material.

Referring now to FIG. 6 by way of example, heating as described above according to embodiments results in a melting of the eutectic 134 (indicated by an arrow including broken lines in FIG. 6 as the eutectic is melting) before any other part of the pair 144 melts. A melting of the eutectic results in the formation of a mixture layer including a mixture of the first element and of the second element, as shown by mixture layer 146 of FIG. 6.

Referring next to FIG. 7 by way of example, after melting of the eutectic 134, the heating temperature may be raised within the predetermined temperature range in order to ensure a further melting of the layer 130 comprising the first element and of the layer 132 comprising the second element. An amount by which the heating temperature may be raised is a function of a consideration of a phase diagram of the first and second elements as mentioned above, in a manner recognizable to one skilled in the art. A further melting of the layer 130 and layer 132 after a melting of the eutectic as described above in relation to FIG. 6 results in an increase in thickness in the mixture layer 146. Mixture layer 146 is a molten layer until joint solidification, which corresponds to a point in time when a temperature of the die-substrate combination drops below a liquidus temperature of the joint.

Referring next to FIG. 8, an increase in thickness of mixture layer 146 brings the mixture layer 146 close to the layers 136 and 140 including the third element, such as, for example, Au. Layers or third element caps 136 and 140, by coming into contact with mixture layer 146, and by being subjected to heating within the predetermined temperature range, are then caused to “break” in the sense of forming intermetallic compound grains by combining with some of the second element in the mixture layer 146 in a well known manner. As the heat and pressure are applied, such as in the thermal compression bonder mentioned above, more and more of the caps 136 and 140 “break” and form the intermetallic compound grains 115, until the temperature of the joint drops below a liquidus temperature of the same, and a joint structure 108 is formed as shown and described above with respect to FIG. 2.

A formation of the joint structures 108 as described above may result in a bonded die-substrate combination such as combination 148 shown in FIG. 9. Thus, as seen in FIG. 9 by way of example, embodiments contemplate the provision of a bonded die-substrate combination (in the sense of at least an electrical bond between die and substrate) including the substrate 102, the die 104, and joint structures 108.

Referring next to FIG. 10, an embodiment contemplates applying an underfill material to a space between the die and the substrate after forming the plurality of joint structures, and curing the underfill material. Preferably, the underfill material 110 may be dispensed in uncured or partially cured form using capillary underfill techniques as described above, such as, for example, by way of an underfill dispensing system 150 as shown in FIG. 10. The dispensing system 150 may be provided by modifying a thermal compression bonder such as one typically used in a NUF process to include the dispensing system 150. System 150 may be controlled to dispense underfill material after a predetermined time corresponding to a time needed for joint formation, that is, corresponding to a time needed for the temperature of the die-substrate combination to drop below a liquidus temperature of the joint. Underfill material may, by way of example, include an epoxy-containing underfill material, or any other of the well known underfill materials as would be within the knowledge of one skilled in the art. The underfill material 110 may then be fully cured, such as by being heated in a cure oven in a well known manner, in order to yield a package such as package 100 of FIG. 1. Preferably, the joint structures are kept at a temperature corresponding to a curing temperature of the underfill material dispensed until after curing of the underfill material in order to prevent damage to the die and/or substrate as a result of a cooling of the joint structures and a mismatch between respective CTE's of the die and of the substrate. To achieve the above, according to one embodiment, the thermal compression bonder and the cure equipment for the underfill material may be placed close to one another as in the case of the current NUF process.

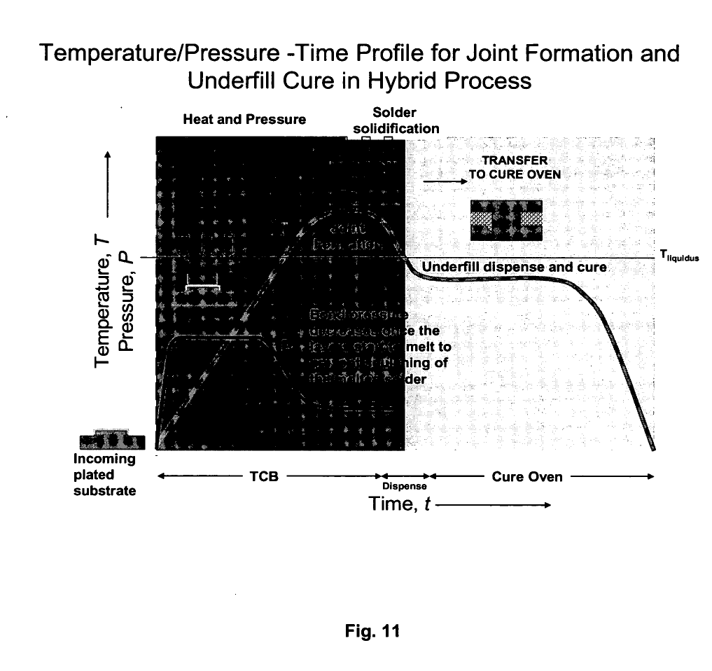

Referring next to FIG. 11, an example is shown of a temperature/pressure profile for joint structure formation and underfill cure according to an embodiment. The profile shown in FIG. 11 is a graph showing: (1) on the left side of the figure, changes versus time in the heating temperature and pressure applied to the die-substrate combination in a thermal compression bonder; and (2) on the right side of the figure, changes versus time in the heating temperature applied to the bonded die-substrate combination in a cure oven to cure an underfill material dispensed between the die and substrate. A purpose of the graph in FIG. 11 is to depict temperature and pressure variation trends according to an embodiment, and, for that reason, the graph axes are not provided with quantitative values. As seen in the thermal compression bonder (TCB) portion of the graph, an incoming plated substrate (that is, a substrate provided with bumping sites as described above) is first disposed in the TCB, and placed in registration with a plated die (that is, a die provided with bumping sites as described above) as shown, at which time a pressure is applied to thus formed die-substrate combination, the pressure being substantially constant at a first pressure value until a temperature in the TCB applied to the die-substrate combination reaches Tliquidus. Tliquidus corresponds to temperature at which pairs of bumping sites between the die and substrate first begin to melt. At the time when the TCB temperature reach Tliquidus, a TCB pressure or bond pressure is shown as being decreased to a substantially constant second pressure value in order to prevent a deformation of the molten solder. The TCB temperature then rises to a maximum temperature corresponding to a joint formation temperature of the joint. The maximum temperature, as noted above, is a function among other things of the information provided in a phase diagram of the first and second elements and of the relative weight percentages of the first and second elements to be melted. The TCB temperature then drops down to below Tliquidus, at which point the joint structures form, and at which point the thus formed die-substrate combination is provided with an underfill material between the die and the substrate at the “Dispense” stage as noted on the “Time” line of the graph. Then, the bonded die-substrate combination is transferred to a cure oven and subjected to an elevated temperature in order to cure the underfill material and to complete a formation of the package.

Advantageously, embodiments provide a reliable, cost-effective and efficient method of bonding a die to a substrate to form a package thereof. Embodiments allow a bonding of a die to a substrate without the necessity of dispensing flux between the die and substrate bumping sites such as in the current NUF process, in this way obviating any entrapped flux-containing underfill material between in the resulting joint structures, and thus obviating problems typically associated with trapped underfill in a NUF process, such as, for example, joint crack initiation as a result of joint fatigue cracking. In addition, embodiments obviate the large number of process stages typically associated with a capillary underflow regime, including obviating stages associated with the provision and removal of flux. In addition, according to an embodiment where underfill is provided between die and substrate, advantageously, the underfill material may be provided while the bonded die-substrate combination is still at an elevated temperature, the underfill material thus being able to be cured before the temperature of the combination drops, thus preventing a stress transfer to the die backend structure during cool down after the formation of the joint structures. Moreover, according to an embodiment, a formation of the joint structures takes from about 5 minutes to about 10 minutes, which is a short time period when compared with current chip attach processes such as a capillary underflow regime typically starting from a flux print process to a completion of a defluxing process.

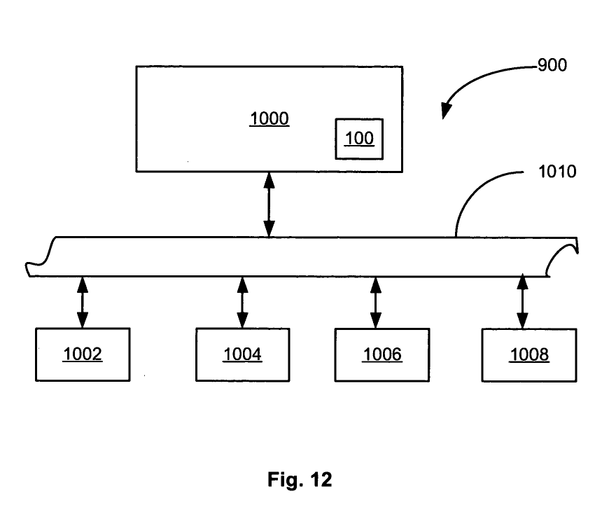

Referring to FIG. 12, there is illustrated one of many possible systems 900 in which embodiments of the present invention may be used. In one embodiment, the electronic assembly 1000 may include a microelectronic package, such as package 100 of FIG. 1. Assembly 1000 may further include a microprocessor. In an alternate embodiment, the electronic assembly 1000 may include an application specific IC (ASIC). Integrated circuits found in chipsets (e.g., graphics, sound, and control chipsets) may also be packaged in accordance with embodiments of this invention. For the embodiment depicted by FIG. 8, the system 90 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A microelectronic package comprising:
a substrate;
a die bonded to the substrate;
a plurality of joint structures electrically bonding the die to the substrate, at least one of the plurality of joint structures comprising a layer including an alloy and intermetallic compound grains dispersed within the alloy, wherein:
the alloy comprises a mixture of a first element and a second element both chosen such that a eutectic of the first element and second element has a melting temperature below a melting temperature of any element other than the eutectic in the at least one joint structure; and
each of the intermetallic compound grains comprises a combination of the second element with a third element, wherein the third element is corrosion resistant.

2. The package of claim 1, wherein the melting temperature of the eutectic is between about 115 degrees Centigrade and about 200 degrees Centigrade.

3. The package of claim 1, wherein the alloy is a eutectic alloy.

4. The package of claim 2, wherein:
the first element comprises Sn;
the second element comprises In;
the alloy comprises SnIn;
the third element comprises Au; and
each the intermetallic compound grains comprise AuIn2.

5. The package of claim 1, wherein:
the layer is a middle layer;
the at least one of the plurality of joint structures further comprises:
a first electrically conductive layer adjacent the substrate;
a second electrically conductive layer adjacent the die;
the middle layer is disposed between the first electrically conductive layer and the second electrically conductive layer.

6. The package of claim 1, wherein the middle layer further comprises a barrier layer adjacent at least one of the first layer and the second layer.

7. The package of claim 6, wherein the barrier layer comprises nickel.

8. The package of claim 1, further comprising an underfill material disposed between the die and the substrate.

9. The package of claim 1, wherein the layer comprises from about 97 to about 99 percent by weight of the alloy, and from about 1 to about 3 percent by weight of the intermetallic compound.

10. A microelectronic substrate comprising:
a wafer;
circuitry disposed within the wafer and including a plurality of bonding pads;
a plurality of bumping sites disposed on respective ones of the bonding pads, each of the bumping sites comprising:
a layer comprising a first element disposed on a corresponding one of the bonding pads;
a layer comprising a second element disposed on the layer comprising the first element;
a eutectic of the first element and the second element disposed at an interface between the first element and the second element, wherein the eutectic has a melting temperature below a melting temperature of any element other than the eutectic in the at least one joint structure; and
a layer comprising a third element disposed on the layer comprising the second element, wherein the third element is corrosion resistant.

11. The substrate of claim 10, wherein the melting temperature of the eutectic is between about 115 degrees Centigrade and about 200 degrees Centigrade.

12. The substrate of claim 11, wherein:
the first element comprises Sn;
the second element comprises In; and
the third element comprises Au.

13. The substrate of claim 10, wherein each of the bumping sites further comprises an electrically conductive layer disposed directly on the bonding pads between the bonding pads and the layer comprising the first element.

14. The substrate of claim 12, wherein each of the bumping sites further comprises a barrier layer disposed between the electrically conductive layer and the layer comprising the first element.

15. The substrate of claim 14, wherein the barrier layer comprises nickel.

16. A method of forming a microelectronic package comprising:
providing a substrate including a plurality of substrate bumping sites;
providing a die including a plurality of die bumping sites;
placing the die onto the substrate such that the substrate bumping sites are placed in registration with corresponding ones of the die bumping sites to form a die-substrate combination including pairs of die and substrate bumping sites;
forming a plurality of joint structures from each pair of die and substrate bumping sites including:
heating the die-substrate combination within a predetermined heating temperature range to form a bonded die-substrate combination, wherein at least one of the plurality of joint structures comprises a layer including an alloy and intermetallic compound grains dispersed within the alloy, the alloy comprising a mixture of a first element and a second element both chosen such that a eutectic of the first element and second element has a melting temperature below a melting temperature of any element other than the eutectic in the at least one joint structure; and each of the intermetallic compound grains comprising a combination of the second element with a third element, wherein the third element is corrosion resistant;
applying pressure to the die-substrate combination during heating.

17. The method of claim 16, wherein the melting temperature of the eutectic is between about 115 degrees Centigrade and about 200 degrees Centigrade.

18. The method of claim 16, wherein the alloy is a eutectic alloy.

19. The method of claim 16, wherein:
each of the substrate bumping sites comprises:
a layer comprising the first element disposed on the substrate;
a layer comprising the second element disposed on the layer comprising the first element;
a eutectic of the first element and the second element disposed at an interface between the first element and the second element; and
a layer comprising the third element disposed on the layer comprising the second element, wherein the third element is corrosion resistant; and
each of the die bumping sites comprises a layer comprising the third element.

20. The method of claim 19, wherein heating comprises:
melting the eutectic such that substantially all of the layer including the first element and all the layer including the second element melt;
forming the intermetallic compound by effecting a breaking of the layer including the third element such that the third element combines with some of the second element to form the intermetallic compound.

21. The method of claim 17, wherein:
the first element comprises Sn;
the second element comprises In; and
the third element comprises Au.

22. The method of claim 16, wherein applying pressure comprises applying a pressure between about 4 Newtons to about 8 Newtons.

23. The method of claim 16, wherein heating and applying pressure comprise using a thermal compression bonder.

24. The method of claim 16, further comprising:
applying an underfill material to a space between the die and the substrate after forming the joint structures; and
curing the underfill material.

25. The method of claim 24, wherein:
each of the substrate bumping sites comprises a first electrically conductive layer adjacent the substrate; and
each of the die bumping sites comprises a second electrically conductive layer adjacent the die.

26. The method of claim 25, wherein at least one of the substrate bumping sites and the die bumping sites each comprise a barrier layer disposed adjacent a corresponding one of the first layer and the second layer.

27. The method of claim 26, wherein the barrier layer comprises nickel.

28. The method of claim 24, further comprising, after forming the joints structures, keeping the bonded die-substrate combination at least at a cure temperature of the underfill material until after curing.

29. A system comprising:
an electronic assembly including:
a microelectronic package comprising:
a substrate;
a die bonded to the substrate;
a plurality of joint structures electrically bonding the die to the substrate, at least one of the plurality of joint structures comprising a layer including an alloy and intermetallic compound grains dispersed within the alloy, wherein:
the alloy comprises a mixture of a first element and a second element both chosen such that a eutectic of the first element and second element has a melting temperature below a melting temperature of any element other than the eutectic in the at least one joint structure; and
each of the intermetallic compound grains comprises a combination of the second element with a third element, wherein the third element is corrosion resistant; and
a main memory coupled to the electronic assembly.

30. The package of claim 29, wherein:
the first element comprises Sn;
the second element comprises In;
the alloy comprises SnIn;
the third element comprises Au; and
each the intermetallic compound grains comprise Auln2.
